(19) United States
(12) Patent Application Publication
(10) Pub. No.: US 2025/0300626 A1
(43) Pub. Date: Sep. 25, 2025

(54) ELASTIC WAVE ELEMENT AND COMMUNICATION DEVICE

(71) Applicant: KYOCERA Corporation, Kyoto-shi, Kyoto (JP)

(72) Inventor: Naofumi KASAMATSU, Nara-shi (JP)

(73) Assignee: KYOCERA Corporation, Kyoto-shi, Kyoto (JP)

(21) Appl. No.: 18/861,002

(22) PCT Filed: Apr. 21, 2023
(86) PCT No.: PCT/JP2023/015898

§ 371 Date: Oct. 28, 2024

(30) Foreign Application Priority Data
Apr. 28, 2022 (JP) 2022-074220

(51) Int. Cl. H03H 9/145; H03H 9/25; H03H 9/64

(52) U.S. Cl. CPC H03H 9/14544; H03H 9/25; H03H 9/6453

(57) ABSTRACT

In an elastic wave element, an interdigital transducer electrode includes a first layer including a first material having conductivity. The first layer has a thickness greater than 100 Å. The first layer is superposed on the piezoelectric layer directly or with a metal layer of smaller than or equal to 100 Å interposed between the first layer and the piezoelectric layer. When a pitch of electrode fingers of the interdigital transducer electrode is p (μm) and a value obtained by dividing a thickness of the first layer (μm) by 2×p^{0.101} is a normalized thickness t1, the normalized thickness t1 and an acoustic velocity V1 (m/s) of a bulk longitudinal wave propagating through the first material satisfy an expression below:

$$2.14 \times 1 {0}^{6} V 1 - 1.16 \times {10}^{- 2} < t 1 < 1.17 \times {10}^{- 5} V 1 - 1.63 \times {10}^{- 2} .$$

### TECHNICAL FIELD

The present disclosure is related to an elastic wave element and a communication device including the elastic wave element.

### BACKGROUND OF INVENTION

A known elastic wave element includes a piezoelectric layer and an interdigital transducer (IDT) electrode superposed on the piezoelectric layer. This elastic wave element utilizes an acoustic wave propagating through the piezoelectric layer (for example, Patent Literature 1). In Patent Literature 1, a thickness of the IDT electrode is proposed. With this thickness of the IDT electrode, spurious generated on the low-frequency side relative to the resonance frequency can be reduced.

### CITATION LIST

### Patent Literature

Patent Literature 1: Japanese Unexamined Patent Application Publication No. 2018-88601

### SUMMARY

In an embodiment of the present disclosure, an elastic wave element includes a supporting substrate, a piezoelectric layer positioned on the supporting substrate, and an interdigital transducer electrode positioned on the piezoelectric layer. The interdigital transducer electrode includes a first layer including a first material having conductivity. The first layer has a thickness greater than 100 Å. The first layer is superposed on the piezoelectric layer directly or with a metal layer of smaller than or equal to 100 Å interposed between the first layer and the piezoelectric layer. The metal layer is in contact with the first layer and the piezoelectric layer. A pitch of electrode fingers of the interdigital transducer electrode is p (μm) and a value obtained by dividing a thickness of the first layer (μm) by 2p^{0.101} is a normalized thickness t1. At this time, the normalized thickness t1 and an acoustic velocity V1 (m/s) of a bulk longitudinal wave propagating through the first material satisfy an expression below:

$$2.14 \times 1 {0}^{- 6} V 1 - 1.16 \times 1 {0}^{- 2} < t 1 < 1.17 \times 1 {0}^{- 5} V 1 - 1.63 \times 1 {0}^{- 2} .$$

In an embodiment of the present disclosure, an elastic wave element includes a supporting substrate, a piezoelectric layer positioned on the supporting substrate, and an interdigital transducer electrode positioned on the piezoelectric layer. The interdigital transducer electrode includes a first layer including a first material having conductivity and

an upper structure that is superposed on an upper surface of the first layer and that includes one or more types of materials different from the first material. The first layer has a thickness greater than 100 Å. The first layer is superposed on the piezoelectric layer directly or with a metal layer of smaller than or equal to 100 Å interposed between the first layer and the piezoelectric layer. The metal layer is in contact with the first layer and the piezoelectric layer. When the upper structure includes an insulating layer of a thickness smaller than or equal to 150 Å included in an upper surface of the interdigital transducer electrode, a portion between the upper surface of the first layer and a lower surface of the insulating layer is a second layer. When the upper structure does not include the insulating layer, a portion between the upper surface of the first layer and the upper surface of the interdigital transducer electrode is the second layer. At this time, the second layer has a thickness greater than 150 Å. A pitch of electrode fingers of the interdigital transducer electrode is p (μm) and a value obtained by dividing a thickness of the second layer (μm) by 2p^{0.101} is a normalized thickness t2. At this time, the normalized thickness t2 and an acoustic velocity V1 (m/s) of a bulk longitudinal wave propagating through the first material satisfy an expression below:

$$4.77 \times {10}^{- 6} V 1 - 1.18 \times 1 {0}^{- 2} < t 2 < 2.52 \times 1 {0}^{- 6} V 1 + 4.09 \times 1 {0}^{- 2} .$$

In an embodiment of the present disclosure, an elastic wave element includes a supporting substrate, a piezoelectric layer positioned on the supporting substrate, and an interdigital transducer electrode positioned on the piezoelectric layer. The interdigital transducer electrode includes a first layer including a first material having conductivity and an upper structure that is superposed on an upper surface of the first layer and that includes one or more types of materials different from the first material. The first layer has a thickness greater than 100 Å. The first layer is superposed on the piezoelectric layer directly or with a metal layer of smaller than or equal to 100 Å interposed between the first layer and the piezoelectric layer. The metal layer is in contact with the first layer and the piezoelectric layer. When the upper structure includes an insulating layer of a thickness smaller than or equal to 150 Å included in an upper surface of the interdigital transducer electrode, a portion between the upper surface of the first layer and a lower surface of the insulating layer is a second layer. When the upper structure does not include the insulating layer, a portion between the upper surface of the first layer and the upper surface of the interdigital transducer electrode is the second layer. At this time, the second layer has a thickness greater than 150 Å. An average density p (g/cm³) of the second layer and an average acoustic velocity V2 (m/s) of a bulk longitudinal wave propagating through the second layer satisfy an expression below:

$$- 135.64 ρ + 4155.6 < V 2 < - 2470.1 ρ + 16872.$$

In an embodiment of the present disclosure, a communication device includes a filter including any one of the above-described elastic wave elements, an antenna connected to the filter, and an integrated circuit element connected to the filter.

### BRIEF DESCRIPTION OF THE DRAWINGS

FIG. 1 is a plan view illustrating a configuration of an elastic wave element according to an embodiment.

FIG. 2 is a sectional view taken along line II-II illustrated FIG. 1.

FIG. 3 is a diagram illustrating a configuration condition of an electrode in the relationship between an acoustic velocity of a bulk longitudinal wave of a first layer of the electrode and the thickness of the first layer.

FIG. 4 is a diagram illustrating a configuration condition of the electrode in the relationship between the acoustic velocity of the bulk longitudinal wave of the first layer of the electrode and the thickness of a second layer of the electrode.

FIG. 5 is a diagram illustrating a configuration condition of the electrode in the relationship between the acoustic velocity of the bulk longitudinal wave of the first layer of the electrode and a total thickness of the electrode.

FIG. 6 is a diagram illustrating a configuration condition of the electrode in the relationship between a density of the second layer of the electrode and an acoustic velocity of a bulk longitudinal wave of the second layer.

FIG. 7A is a sectional view illustrating another example of a composite substrate of the elastic wave element.

FIG. 7B is a sectional view illustrating yet another example of the composite substrate of the elastic wave element.

FIG. 8 is a diagram illustrating an example of a simulation result.

FIG. 9 is a diagram illustrating an example of a simulation result with a material of a piezoelectric layer different from a material of the piezoelectric layer of FIG. 8.

FIG. 10 is a diagram illustrating an example of a simulation result with a configuration below the piezoelectric layer different from that of FIG. 8.

FIG. 11 is a diagram illustrating an example of a simulation result with a pitch of electrode fingers different from that of FIG. 8.

FIG. 12A is a diagram illustrating an example of a characteristic of the elastic wave element.

FIG. 12B is a diagram illustrating an example of the characteristic of the elastic wave element in which a material of the first layer and a material of the second layer are reversed in the elastic wave element according to FIG. 12A.

FIG. 13A is a schematic diagram illustrating another example of a laminated structure related to the electrode.

FIG. 13B is a schematic diagram illustrating still another example of the laminated structure related to the electrode.

FIG. 13C is a schematic diagram illustrating still another example of the laminated structure related to the electrode.

FIG. 13D is a schematic diagram illustrating still another example of the laminated structure related to the electrode.

FIG. 13E is a schematic diagram illustrating still another example of the laminated structure related to the electrode.

FIG. 14 is a circuit diagram schematically illustrating a configuration of a splitter including the elastic wave element according to the embodiment.

FIG. 15 is a block diagram illustrating a configuration of a communication device including the elastic wave element according to the embodiment.

### DESCRIPTION OF EMBODIMENTS

Hereinafter, an embodiment according to the present disclosure is described with reference to the drawings. The drawings to be used in the description below are schematic. Accordingly, for example, the ratio of dimensions or the like in the drawings does not necessarily agree with the actual ratio of dimensions or the like. The ratios of dimensions or the like do not necessarily agree between the drawings. A specific shape and/or a dimension or the like may be exaggerated and the details may be omitted. However, the above description does not deny a case where an actual shape and/or a dimension may agree with that of the drawings or a case where the characteristic of the shape and/or dimension may be extracted from the drawings.

### Outline of Embodiment

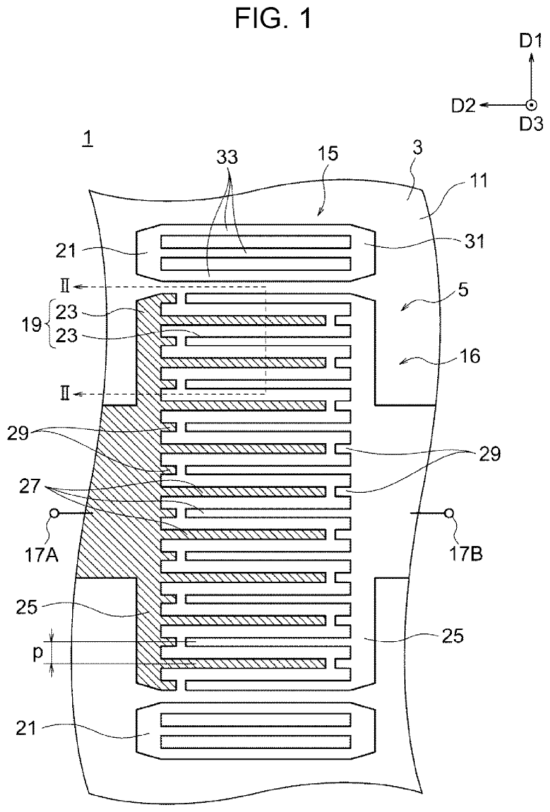

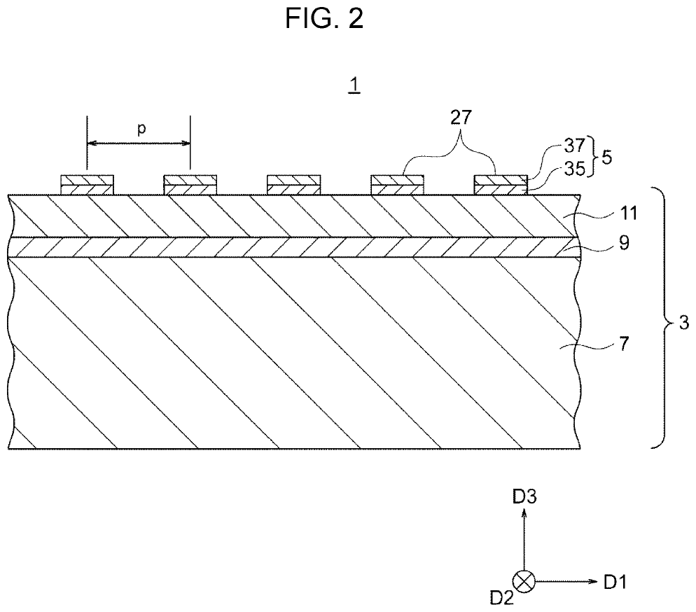

FIG. 1 is a schematic plan view illustrating an example of a configuration of an elastic wave element 1 according to the embodiment. FIG. 2 is a sectional view taken along line II-II illustrated FIG. 1.

For convenience, a D1D2D3 rectangular coordinate system is provided in these drawings. As can be understood from explanation to be described later, a D3 direction is a normal direction to an upper surface of a composite substrate 3. A D1 direction is a propagation direction of an acoustic wave propagating along an upper surface of the composite substrate 3. A D2 direction is perpendicular to the D1 direction and the D3 direction. Regarding the elastic wave element 1, any direction may be defined as an upper direction or a lower direction. However, for convenience, the terms upper surface and lower surface may be used with the +D3 side defined as the upper direction in the description of the embodiment.

The elastic wave element 1 includes, for example, the composite substrate 3 having piezoelectricity at least in an upper surface of the composite substrate 3 and an IDT (interdigital transducer) electrode 19 positioned on the composite substrate 3. The composite substrate 3 includes, for example, a piezoelectric layer 11 included in the upper surface of the composite substrate 3. As illustrated in FIG. 2, the IDT electrode 19 includes, for example, a first conductor layer 35 (an example of a first layer) superposed on the piezoelectric layer 11 and a second conductor layer 37 (an example of a second layer) superposed on the first conductor layer 35.

An electrical signal input to the IDT electrode 19 is converted into an acoustic wave propagating in the piezoelectric layer 11. Also, the acoustic wave propagating in the piezoelectric layer 11 is converted into an electrical signal to be output from the IDT electrode 19. For example, resonance and/or filtering of the electrical signal is realized by utilizing resonance of the acoustic wave.

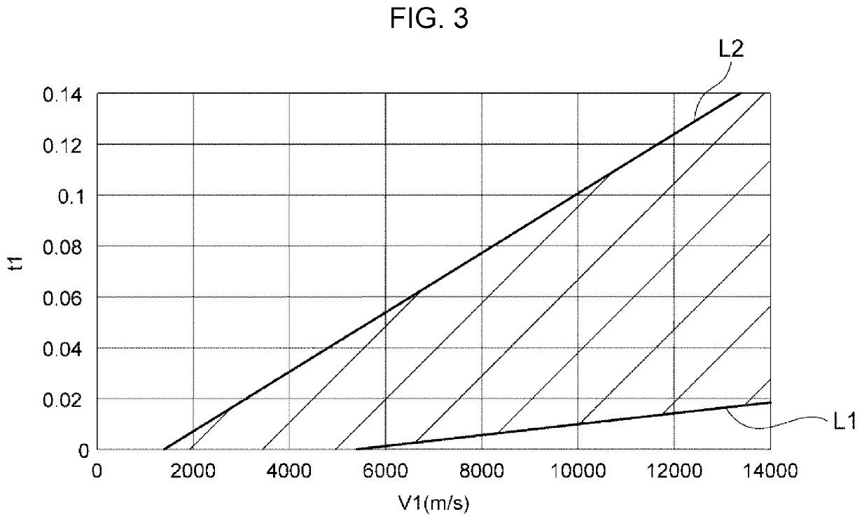

FIGS. 3 to 6 are diagrams illustrating a configuration condition of the first layer and the second layer (for example, the first conductor layer 35 and the second conductor layer 37). Regarding the configurations of the first layer and the second layer, a combination of at least two selected from the group consisting of normalized thicknesses (t1. t2, and t3) of the first layer, the second layer, and the first and second layers, acoustic velocities (V1 and V2), and a density (p) falls within hatched regions of FIGS. 3 to 6. In this way, a characteristic of the elastic wave element 1 is improved. For example, spurious is reduced on the high-frequency side relative to an anti-resonance frequency.

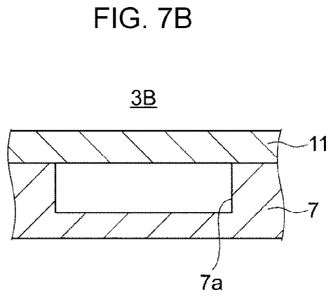

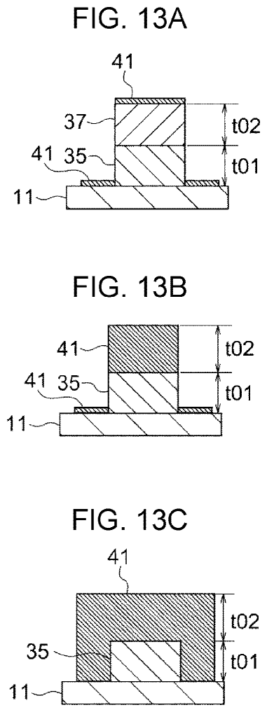

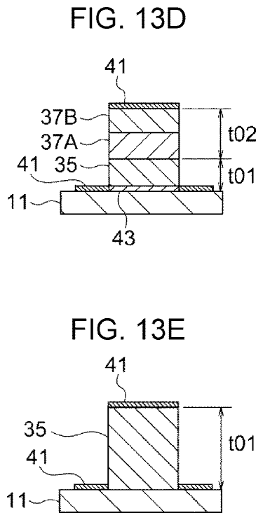

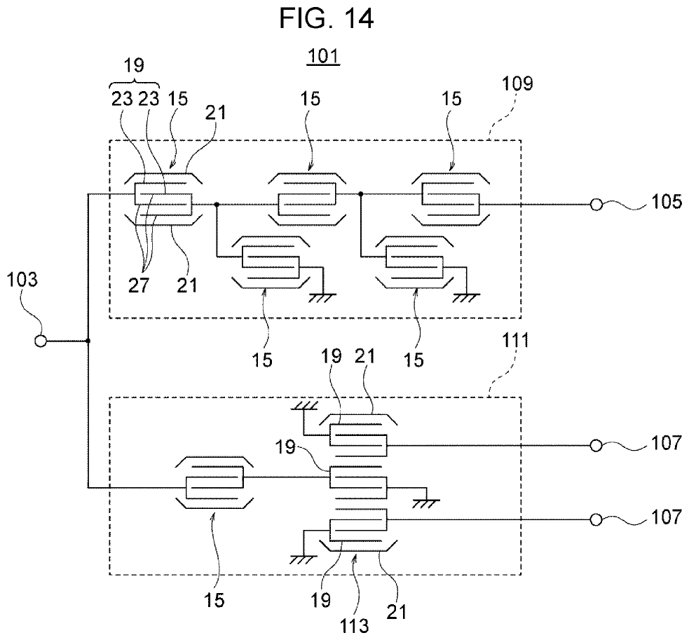

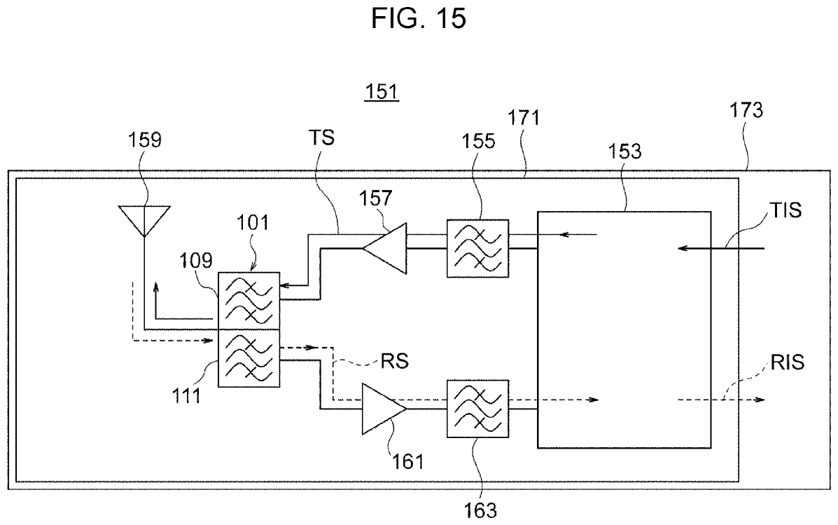

The outline of the elastic wave element 1 according to the embodiment has been described. Hereinafter, generally, the embodiment will be described in the following order.
1. Basic configuration of elastic wave element 1 (FIGS. 1 and 2)
   1.1. Composite substrate 3
   1.2. Electrode layer (IDT electrode 19)
   1.3. Other configurations
2. Configuration condition related to IDT electrode
   2.1. Definitions of acoustic velocity and normalized thickness
   2.2. Ranges of parameter values (FIGS. 3 to 6)
   2.3. Derivation process of configuration condition (FIGS. 7A to 12B)
      2.3.1. Outline of derivation process
      2.3.2. Characteristic to be satisfied
      2.3.3. Conditions of composite substrate
      2.3.4. Acoustic velocity of first layer
3. Other examples of electrode (FIG. 13)
4. Splitter 101 (FIG. 14)
5. Communication device (FIG. 15)
6. Summarization of embodiment

### 1. Basic Configuration of Elastic Wave Element

The elastic wave element 1 illustrated in FIG. 1 includes a so-called single-port acoustic wave resonator (resonator 15). For example, when an electrical signal of a predetermined frequency is input to one of terminals 17A and 17B which are conceptually and schematically indicated, the resonator 15 can generate resonance and output a signal generating the resonance from the other of the terminals 17A and 17B. In the following description, for convenience, the elastic wave element 1 and the resonator 15 are not necessarily distinguished from each other.

As has been described, the elastic wave element 1 (resonator 15) includes the composite substrate 3 and the IDT electrode 19. The elastic wave element 1 also includes a pair of reflectors 21 positioned on both sides of the IDT electrode 19. From another viewpoint, the elastic wave element 1 includes the composite substrate 3 and an electrode layer 5 superposed on the composite substrate 3. The electrode layer 5 includes the IDT electrode 19 and the pair of reflectors 21. From yet another viewpoint, the electrode layer 5 includes the first conductor layer 35 and the second conductor layer 37, which have been described.

In the composite substrate 3 and the electrode layer 5, a region where the IDT electrode 19 and the pair of reflectors 21 are positioned is included in the resonator 15. As described above, the resonator 15 includes not only the IDT electrode 19 and the pair of reflectors 21 but also at least part of the composite substrate 3 on the upper surface side. However, in the description of the embodiment, for convenience, the resonator 15 is described as if the resonator 15 includes only the IDT electrode 19 and the pair of reflectors 21 (a configuration without composite substrate 3) in some cases. A region of the resonator 15 where the IDT electrode 19 is disposed (a configuration without a region where the reflectors 21 are positioned) is also a resonator. This resonator may be referenced as a resonator 16.

The acoustic wave utilized by the elastic wave element 1 may be of an appropriate type. For example, the acoustic wave may be a SAW (surface acoustic wave), a BAW (bulk acoustic wave), a boundary acoustic wave, or a plate wave (however, these acoustic waves are not necessarily distinguished from each other). In the description of the embodiment, a form in which a plate wave of a comparatively high velocity is utilized as the acoustic wave may be described as an example without specification. From another viewpoint, a form in which the resonance frequency is comparatively high (for example, higher than or equal to 4 GHZ) may be described as an example.

The plate wave may be, for example, a Lamb wave or a plate wave of an SH (shear horizontal) type. Main components of the Lamb wave are a displacement component in the propagation direction (D1 direction) and a displacement component in a thickness direction (D3 direction) of a piezoelectric body. Furthermore, the Lamb wave may be, for example, in an A mode (asynchronous mode) or an S mode (synchronous mode). Furthermore, the order of the A mode or the S mode is arbitrary. For example, the Lamb wave in the A mode may be a Lamb wave in an A1 mode in which the number of nodes in the thickness direction is 1.

Furthermore, the acoustic wave (bulk wave) may be a wave in a thickness slip mode (may also be understood as a type of the Lamb wave). In this mode, the piezoelectric layer 11 vibrates such that an upper surface and a lower surface of the piezoelectric layer 11 are translated from each other in a direction parallel to these surfaces. Furthermore, the order of this mode is also arbitrary. For example, the order in the thickness slip mode may be primary in which the number of nodes in the thickness direction is one. In other words, in the thickness slip mode, about a half of the piezoelectric layer 11 on the upper surface side and about a half of the piezoelectric layer 11 on the lower surface side may be displaced to sides opposite from each other in a direction along a plane. When the thickness slip mode is utilized, unlike the description of the embodiment, propagation of the acoustic wave in the D1 direction is not necessarily required.

### (1.1. Composite Substrate)

The composite substrate 3 may have any of various configurations as long as the composite substrate 3 includes the piezoelectric layer 11 included in the upper surface of the composite substrate 3. In the description of the embodiment, a “layer” and a “film” are synonymous. The composite substrate 3 exemplified in FIG. 2 includes a supporting substrate 7, an intermediate layer 9 (an example of an acoustic film) positioned on the supporting substrate 7, and the piezoelectric layer 11 positioned on the intermediate layer 9. Examples of other configurations of the composite substrate 3 are described in “2.3. Derivation process of configuration condition”, which will be described later, with reference to FIGS. 7A and 7B.

The piezoelectric layer 11 contributes to, together with the IDT electrode 19, the conversion from the electrical signal to the acoustic wave and the conversion from the acoustic wave to the electrical signal. The acoustic wave intended to be used propagates mainly through the piezoelectric layer 11. The supporting substrate 7 contributes to, for example, reinforcement of the composite substrate 3. The intermediate layer 9 contributes to, for example, joining of the piezoelectric layer 11 and the supporting substrate 7 to each other and/or confinement of the acoustic wave propagating through the piezoelectric layer 11.

The piezoelectric layer 11 includes, for example, a single crystal having piezoelectricity. Examples of the material included in such a single crystal include lithium tantalate (LiTaO₃, may be abbreviated as LT hereinafter), lithium niobate (LiNbO₃, may be abbreviated as LN hereinafter), and crystal (SiO₂). Cut angles of these single crystals are arbitrary. The piezoelectric layer 11 may include a polycrystal.

The thickness of the piezoelectric layer 11 is arbitrary. For example, when double a pitch p of electrode fingers 27, which will be described later, is λ, the thickness of the piezoelectric layer 11 may be greater than or equal to 0.05λ or greater than or equal to 0.1λ. With such a thickness, for example, the acoustic wave propagating through the piezoelectric layer 11 can be utilized. Furthermore, for example, the thickness of the piezoelectric layer 11 may be smaller than or equal to 1.0λ. In this case, for example, insertion loss can be reduced and an acoustic wave in a comparatively high-velocity mode can be utilized.

The material of the intermediate layer 9 may be an arbitrary material in accordance with the purpose of the intermediate layer 9. For example, the intermediate layer 9 may include a material in which the acoustic velocity is lower than the acoustic velocity of the piezoelectric layer 11. That is, the intermediate layer 9 may be a low-acoustic velocity film. This facilitates confinement of the acoustic wave intended to be utilized within the piezoelectric layer 11. The acoustic velocity referred to herein may be, for example, as is the case with the acoustic velocity in the electrode, a bulk longitudinal wave acoustic velocity and an acoustic velocity calculated by using v (Young's modulus/density). The acoustic velocity in the electrode will be described later. Specific examples of the material of the low-acoustic velocity film include silicon dioxide (SiO₂), tantalum oxide (Ta₂O₃), silicon oxynitride (Si₂N₂O), and glass. Alternatively, a chemical compound formed by adding fluorine, carbon, boron, or the like to SiO₂ may be used.

The thickness of the intermediate layer 9 may be an arbitrary thickness in accordance with the purpose of the intermediate layer 9. For example, the thickness of the intermediate layer 9 may be smaller than (illustrated example), equivalent to, or greater than the thickness of the piezoelectric layer 11. The thickness of the intermediate layer 9 is, for example, greater than or equal to 0.012 or greater than or equal to 0.12 and smaller than or equal to 12, smaller than or equal to 0.52, or smaller than or equal to 0.22. Out of the above-described upper limits and lower limits, an arbitrary upper limit and an arbitrary lower limit may be combined with each other. When such a thickness is adopted, for example, insertion loss is reduced in a form in which the intermediate layer 9 is a low-acoustic velocity film. Of course, the thickness of the intermediate layer 9 may be a thickness outside the above-described range.

The material and the dimensions of the supporting substrate 7 are arbitrary. The material of the supporting substrate 7 may have a lower thermal expansion coefficient than the thermal expansion coefficient of the piezoelectric layer 11 and the like. In this case, for example, a probability that a frequency characteristic of the resonator 15 varies due to temperature variation can be reduced. Examples of such a material include a semiconductor such as a silicon (Si), a single crystal such as sapphire, and ceramic such as an aluminum oxide sintered body. The supporting substrate 7 may be configured by laminating a plurality of layers that are made of materials different from each other. The thickness of the supporting substrate 7 is greater than the thickness of, for example, the piezoelectric layer 11.

### (1.2. Electrode Layer (IDT Electrode))

The configuration of the electrode layer 5 (the material, the thickness, and the like) is in common with, for example, the configurations of the IDT electrode 19 and the reflectors 21 (and wires connected to these). However, the configurations may differ in parts.

The entirety of the first conductor layer 35 (the example of the first layer) includes the same material (may be referred to as a first material). The second conductor layer 37 may include one or more materials. As a form in which the second conductor layer 37 includes two or more materials is, for example, a form in which the second conductor layer 37 is configured by laminating two or more layers that are formed of materials different from each other. However, in the description of the embodiment, unless otherwise specified, the entirety of the second conductor layer 37 includes the same material.

The materials of the first conductor layer 35 and the second conductor layer 37 are, for example, metal. The specific type of the metal is arbitrary as long as the configuration condition, which will be described later with reference to FIGS. 3 to 6, is satisfied. Examples of the metal may include aluminum (Al), copper (Cu), tungsten (W), iridium (Ir), tantalum (Ta), and an alloy including two or more of these. The thicknesses of the first conductor layer 35 and the second conductor layer 37 are also arbitrary as long as the configuration condition, which will be described later, is satisfied.

The IDT electrode 19 includes a pair of comb-shaped electrodes 23. Referring to FIG. 1, one of the comb-shaped electrodes 23 is hatched for clarity. Each of the comb-shaped electrodes 23 includes, for example, a busbar 25, a plurality of electrode fingers 27 extending from the busbar 25 so as to be parallel to each other, and dummy electrodes 29 projecting between the plurality of electrode fingers 27 from the busbar 25. The pair of comb-shaped electrodes 23 are disposed such that the plurality electrode fingers 27 interdigitate (intersect).

The busbar 25 generally has, for example, a shape that has a fixed width and linearly extends in the propagation direction of the acoustic wave (D1 direction). A pair of busbars 25 face each other in a direction (D2 direction) intersecting the propagation direction of the acoustic wave. Unlike the illustrated example, the busbar 25 may have a varying width or may be inclined relative to the propagation direction of the acoustic wave.

Each of the electrode fingers 27 generally has, for example, a shape that has a fixed width and linearly extends in a direction (D2 direction) perpendicular to the propagation direction of the acoustic wave. However, the width of the electrode finger 27 may vary depending on the positions in a length direction (D2 direction). Examples of such electrode fingers 27 include electrode fingers utilizing a so-called piston mode. In each of the comb-shaped electrodes 23, the plurality of electrode fingers 27 are arranged in the propagation direction (D1) of the acoustic wave. Furthermore, the plurality of electrode fingers 27 of one of the comb-shaped electrodes 23 and the plurality of electrode fingers 27 of the other comb-shaped electrode 23 are basically alternately arranged.

A pitch p of the plurality of electrode fingers 27 (a center-to-center distance between two electrode fingers 27 adjacent to each other) are basically uniform in the IDT electrode 19. However, a narrow pitch portion or a wide pitch portion may be provided in part of the IDT electrode 19. In the narrow pitch portion, the pitch p is smaller than the pitch p in the majority of other portions. In the wide pitch portion, the pitch p is greater than the pitch p in the majority of other portions. Furthermore, a reduced portion may exist at part of the IDT electrode 19. In the reduced portion, the electrode fingers 27 are substantially reduced.

In the description of the embodiment, unless otherwise specified, the pitch p refers to a pitch in a portion (the majority of the plurality of electrode fingers 27) other than unusual portions such as the narrow pitch portion, the wide pitch portion, and the reduced portion as described above. When the pitch of the majority of the electrode fingers 27 other than the unusual portions also varies, the following value may be used as the value of the pitch p: an average value of values of the pitch of most of the electrode fingers 27 (for example, 80% of the entirety of the electrode fingers 27 selected so as to minimize the variance).

As can be understood from later description, the pitch p may be set in accordance with an intended resonance frequency. For example, the pitch p may be greater than or equal to 0.1 μm, greater than or equal to 0.3 μm, or greater than or equal to 0.5 μm and smaller than or equal to 10 μm, smaller than or equal to 5 μm, or smaller than or equal to 2 μm. Out of the above-described upper limits and lower limits, an arbitrary upper limit and an arbitrary lower limit may be combined with each other.

The number of the electrode fingers 27 may be appropriately set in accordance with the electrical characteristic or the like required for the resonator 15. Since FIG. 1 is a schematic view, the number of the electrode fingers 27 in the illustration is small. Actually, a greater number of the electrode fingers 27 than that in the illustration may be arranged. This is also applied in the same or similar manner to strip electrodes 33 of the reflectors 21, which will be described later.

The lengths of the plurality of electrode fingers 27 are, for example, equivalent to each other. Unlike the illustrated example, a so-called apodization may be applied to the IDT electrode 19. In the apodization, the lengths of the plurality of electrode fingers 27 (so-called intersecting widths from another viewpoint) vary depending on the positions in the propagation direction (D1 direction) of the acoustic wave. The length and thickness of the electrode fingers 27 may be appropriately set in accordance with the required electrical characteristic or the like.

The dummy electrodes 29 generally have, for example, a shape that has a fixed width and projects in a direction perpendicular to the propagation direction of the acoustic wave. The width of the dummy electrodes 29 is, for example, equivalent to the width of the electrode fingers 27. The plurality of dummy electrodes 29 are arranged in a pitch equivalent to that of the plurality of electrode fingers 27. A distal end of each of the dummy electrodes 29 of one of the comb-shaped electrodes 23 faces a distal end of a corresponding one of the electrode fingers 27 of the other comb-shaped electrode 23 with a gap interposed therebetween. The IDT electrode 19 does not necessarily include the dummy electrodes 29.

The pair of reflectors 21 are positioned on both sides of the IDT electrode 19 in the propagation direction of the acoustic wave. For example, each of the reflectors 21 may be electrically floating or provided with a reference potential. The reflector 21 has, for example, a grid shape. That is, the reflector 21 includes a pair of busbars 31 facing each other and a plurality of strip electrodes 33 extending between the pair of busbars 31. A pitch of the plurality of strip electrodes 33 and a pitch between an electrode finger 27 and a strip electrode 33 adjacent to each other are, for example, equivalent to the pitch of the plurality of electrode fingers 27.

When a voltage is applied to the pair of comb-shaped electrodes 23, the voltage is applied to the piezoelectric layer 11 by the plurality of electrode fingers 27, and the piezoelectric layer 11 vibrates. That is, the acoustic wave is excited. Out of acoustic waves with various wavelengths propagating in various directions, acoustic waves which propagate in an arrangement direction of the plurality of electrode fingers 27 and for which the pitch p of the plurality of electrode fingers 27 is approximately a half wavelength (λ/2) tend to increase in amplitude because a plurality of waves having been excited by the plurality of electrode fingers 27 are in phase with each other and superposed on each other. Furthermore, the acoustic waves propagating through the piezoelectric layer 11 are converted into electrical signals by the plurality of electrode fingers 27. At this time, as is the case with the excitation of the acoustic waves, regarding the electrical signals converted from the acoustic waves which propagate in the arrangement direction of the plurality of electrode fingers 27 and for which the pitch p of the plurality of electrode fingers 27 is approximately the half wavelength (λ/2), the intensity of these electrical signals tends to increase. Due to the above-described actions (and other actions description of which is omitted herein), the elastic wave element 1 functions as, for example, a resonator with a frequency of the acoustic wave for which the pitch p is the half wavelength as the resonance frequency.

### (1.3. Other Configurations)

The elastic wave element 1 may be appropriately packaged. The elastic wave element 1 may be packaged, for example, in a form in which the illustrated configuration is mounted on a substrate (not illustrated) such that the upper surface of the piezoelectric layer 11 faces the substrate with a gap interposed therebetween and the resulting structure is sealed from above with resin or in a wafer level packaging type in which a box-shaped cover is provided on the piezoelectric layer 11.

### 2. Configuration Condition Related to IDT Electrode

Hereinafter, with reference to FIGS. 3 to 6, ranges of values of parameters related to the first layer and the second layer according to the embodiment are described. The parameters include normalized thicknesses t1, t2, and t3, acoustic velocities V1 and V2, and the density ρ. Examples of the first layer and the second layer are the first conductor layer 35 and the second conductor layer 37. The elastic wave element 1 according to the embodiment may satisfy only one of four types of ranges illustrated in FIGS. 3 to 6, two or three of the four types of ranges, or all of the four types of ranges.

As will be described later with reference to FIGS. 13A to 13E, the second layer is not limited to the second conductor layer 37. However, in the description herein, for convenience, the terms first conductor layer 35 and second conductor layer 37 may be used instead of the terms first layer and second layer without specification. Furthermore, a layer made by combining the first layer and the second layer may be referred to as a third layer.

### (2.1. Definitions of Acoustic Velocity and Normalized Thickness)

FIGS. 3 to 6 illustrate conditions related to the acoustic velocity V1 of the first layer or the acoustic velocity V2 of the second layer. The acoustic velocities V1 and V2 are acoustic velocities (m/s) of a bulk longitudinal wave propagating through the first layer and the second layer. Whether an actual product satisfies the condition illustrated in FIGS. 3 to 6 may be identified by measuring the acoustic velocity of the bulk longitudinal wave or may be calculated with V (Young's modulus/density). Unless otherwise specified, the acoustic velocities V1 and V2 used in a process to derive FIGS. 3 to 6 are calculated with V (Young's modulus/density).

FIGS. 3 to 5 illustrate the conditions related to the normalized thickness t1 of the first layer, the normalized thickness t2 of the second layer, and a normalized thickness t3 (=t1+t2) of a third layer (the first layer and the second layer). The normalized thickness herein is a value dividing the thickness (μm) of each of the layers by a calculated with the following expression.

α=2p^{0.101}

In basic theory, as has been described, the wavelength λ is double the pitch p of the electrode fingers 27 and λ=2p. Also in basic theory, an acoustic velocity V of the piezoelectric layer 11, the wavelength λ, and a resonance frequency fr of the resonator 15 (16) satisfy the following relationship: V=fr×λ. In general, the thicknesses of various layers of the elastic wave element 1 are normalized when divided by 2p. Thus, normalized thicknesses applicable to any resonance frequency fr can be obtained.

However, the above-described normalization is based on the satisfaction of the relationship V=fr×λ for the acoustic velocity V of the piezoelectric layer 11. Accordingly, for example, 2p is not necessarily adequate as a value for normalizing the thickness of the first conductor layer 35 when the configuration condition is set in the relationship between the acoustic velocity V1 of the first conductor layer 35 and the thickness of the first conductor layer 35. Thus, a described above is used.

The above-described a is a value obtained by a numerical analysis based on a result of simulation calculation. Specifically, first, the simulation calculation is performed under various conditions in which values of the pitch p and the acoustic velocity V1 of the first conductor layer 35 are varied from each other. The resonance frequency fr of the resonator 15 (16) is obtained by this simulation calculation. Then, the acoustic velocity V1 and the pitch p used in the simulation calculation and the value of the resonance frequency fr obtained by the simulation calculation are subjected to the numerical analysis. Thus, a function α(p) that is appropriate for the V1=fr×α(p) is obtained. This function α(p) is α=2p^{0.101} described above.

### (2.2. Ranges of Parameter Values)

FIG. 3 is a diagram illustrating the configuration condition of the first layer in the relationship between the normalized thickness t1 of the first layer (for example, the first conductor layer 35) and the acoustic velocity V1 of the first layer.

In FIG. 3, the horizontal axis represents the acoustic velocity V1 (m/s). The vertical axis represents the normalized thickness t1. The hatched region represents ranges of the acoustic velocity V1 and the normalized thickness t1 of the elastic wave element 1 according to the embodiment. Line L1 represents a lower limit of the normalized thickness t1 of the above-described range. Line L2 represents an upper limit of the normalized thickness t1 of the above-described range.

When the normalized thickness t1 that falls within the hatched region is expressed by inequalities using expressions expressing lines L1 and L2, the inequalities are as follows:

$$2.14 \times 1 {0}^{- 6} V 1 - 1.16 \times 1 {0}^{- 2} < t 1 < 1.17 \times 1 {0}^{- 5} V 1 - 1.63 \times 1 {0}^{- 2} .$$

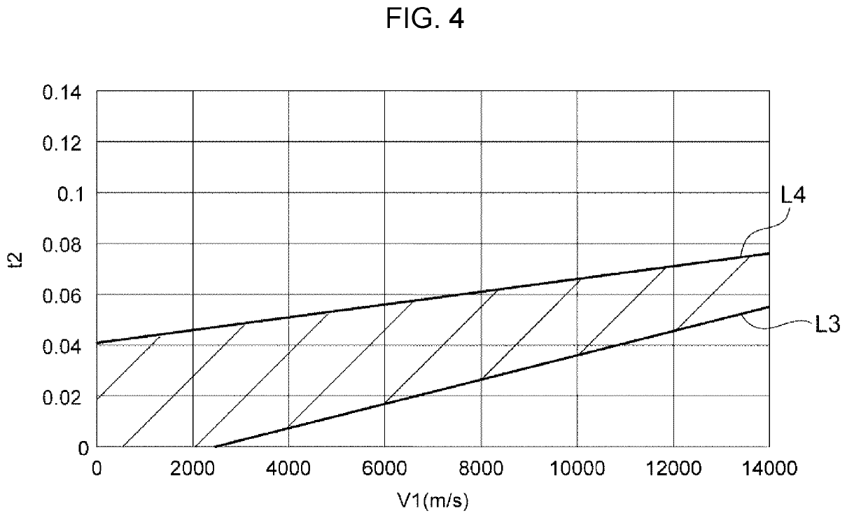

FIG. 4 is a diagram illustrating the configuration condition of the electrode layer 5 in the relationship between the normalized thickness t2 of the second layer (for example, the second conductor layer 37) and the acoustic velocity V1 of the first layer.

In FIG. 4, the horizontal axis represents the acoustic velocity V1 (m/s). The vertical axis represents the normalized thickness t2. The hatched region represents ranges of the acoustic velocity V1 and the normalized thickness t2 of the elastic wave element 1 according to the embodiment. Line L3 represents a lower limit of the normalized thickness t2 of the above-described range. Line L4 represents an upper limit of the normalized thickness t2 of the above-described range.

When the normalized thickness t2 that falls within the hatched region is expressed by inequalities using expressions expressing lines L3 and L4, the inequalities are as follows:

$$4.77 \times {10}^{- 6} V 1 - 1.18 \times 1 {0}^{- 2} < t 2 < 2.52 \times 1 {0}^{- 6} V 1 + 4.09 \times 1 {0}^{- 2} .$$

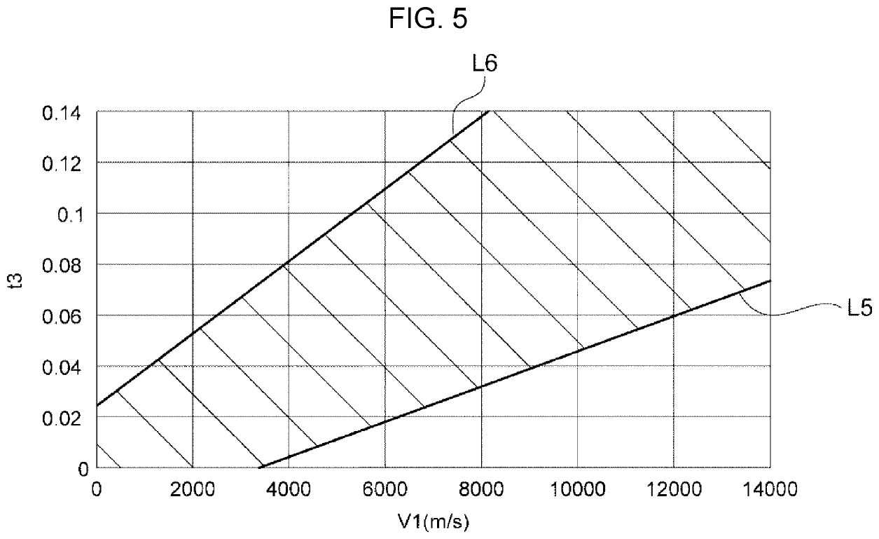

FIG. 5 is a diagram illustrating the configuration condition of the electrode layer 5 in the relationship between the normalized thickness t3 (=t1+t2) of the third layer which is a combination of the first layer (for example, the first conductor layer 35) and the second layer (for example, the second conductor layer 37) and the acoustic velocity V1 of the first layer.

In FIG. 5, the horizontal axis represents the acoustic velocity V1 (m/s). The vertical axis represents the normalized thickness t3. The hatched region represents ranges of the acoustic velocity V1 and the normalized thickness t3 of the elastic wave element 1 according to the embodiment. Line L5 represents a lower limit of the normalized thickness t3 of the above-described range. Line L6 represents an upper limit of the normalized thickness t3 of the above-described range.

When the normalized thickness t3 that falls within the hatched region is expressed by inequalities using expressions expressing lines L5 and L6, the inequalities are as follows:

$$6.91 \times 1 {0}^{- 6} V 1 - 2.34 \times 1 {0}^{- 2} < t 3 < 1.42 \times {10}^{- 5} V 1 + 2.45 \times 1 {0}^{- 2} .$$

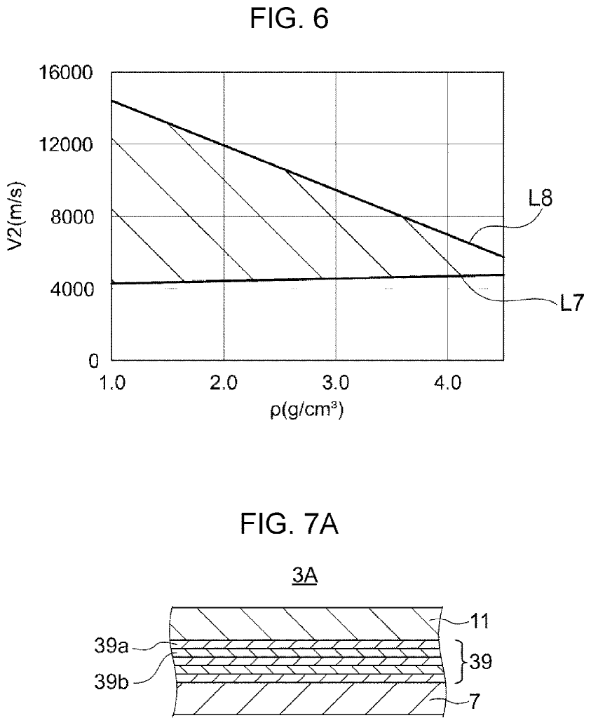

FIG. 6 is a diagram illustrating the configuration condition of the second layer in the relationship between the density p (g/cm³) of the second layer (for example, the second conductor layer 37) and the acoustic velocity V2 (m/s) of the second layer.

In FIG. 6, the horizontal axis represents the density ρ (g/cm³). For avoiding confusion with densities of other layers, the density ρ of the second layer may be referred to as a density ρ2. The vertical axis represents the acoustic velocity V2 (m/s). The hatched region represents ranges of the density p and the acoustic velocity V2 of the elastic wave element 1 according to the embodiment. Line L7 represents a lower limit of the acoustic velocity V2 of the above-described range. Line L8 represents a lower limit of the acoustic velocity V2 of the above-described range.

When the acoustic velocity V2 that falls within the hatched region is expressed by inequalities using expressions expressing lines L7 and L8, the inequalities are as follows:

$$- 135.64 ρ + 4155.6 < V 2 < - 2470.1 ρ + 16872.$$

The values of each type of the parameters of the elastic wave element 1 according to the embodiment may be values that fall within a range further reduced from the range (hatched region) illustrated in FIGS. 3 to 6. For example, the values of the parameter may be set so as to fall within the following range: the width in a direction parallel to the vertical axis is ½ to ⅓ of the width in the direction parallel to the vertical axis in the range illustrated in FIGS. 3 to 6, and a center line is coincident with a center line of the range indicated in FIGS. 3 to 6.

### (2.3. Derivation Process of Configuration Condition)

### (2.3.1. Outline of Derivation Process)

The configuration condition related to the IDT electrode 19 illustrated in FIGS. 3 to 6 is derived by the following procedure.

The simulation calculation to obtain the characteristic of the resonator 15 is performed on a plurality of cases in which the values of the parameters (t1, t2, t3, V1, V2 and φ related to the configuration condition are varied from each other. For example, as illustrated in FIG. 3, in the case where the configuration condition is obtained in the relationship between the acoustic velocity V1 and the normalized thickness t1, the simulation calculation is performed on a plurality of cases in which various values are set at least in each of the acoustic velocity V1 and the normalized thickness t1.

Actually, for example, in the case where the configuration condition is obtained in the relationship between the acoustic velocity V1 and the normalized thickness t1 illustrated in FIG. 3, the simulation calculation is performed on an enormous number of cases by setting various values in other parameters. Specifically, the simulation calculation is performed on the enormous number of cases where, in addition to the acoustic velocities V1 and V2, the normalized thicknesses t1 and t2 (and t3), and the density p of the second layer, values of the other parameters (for example, the pitch p) are varied from each other. Thus, a single database for obtaining FIGS. 3 to 6 is created.

The ranges in the simulation calculation of the parameters illustrated in FIGS. 3 to 6 are as follows.
V1: 3300 to 13300 m/s
V2: 3300 to 13300 m/s
t1: 0.0035 to 0.164
t2: 0.0070 to 0.087
t3: 0.0105 to 0.251
ρ2: 2.0 to 5.0 g/cm³

Cases where the characteristic obtained by the simulation calculation satisfies a predetermined requirement are extracted from the above-described enormous number of cases. The predetermined requirement will be described later.

The values of the parameters of the extracted cases can be plotted in a graph having the horizontal axis and the vertical axis similar to FIGS. 3 to 6. A case with the smallest value on the vertical axis and a case with the largest value on the vertical axis can be extracted from a plurality of cases with the same values in the horizontal axis. For example, in a graph similar to or the same as FIG. 3, a case with the smallest normalized thickness t1 and a case with the greatest normalized thickness t1 can be extracted from a plurality of cases with the same acoustic velocity V1. The lower limit value and an upper limit value on the vertical axis with which the characteristic of the resonator 15 satisfies the predetermined requirement are obtained for the various values on the horizontal axis by performing such a procedure for the various values on the horizontal axis. Actually, it is not necessary to create a graph with the above-described plotting. It is sufficient that a procedure as described above be substantially performed.

An approximate line is obtained for the lower limit values on the vertical axis identified for the various values on the horizontal axis. This approximate line corresponds to lines L1, L3, L5, and L7 representing the lower limits of the ranges illustrated in FIGS. 3 to 6. Likewise, an approximate line is obtained for the upper limit values on the vertical axis identified for the various values on the horizontal axis. This approximate line corresponds to lines L2, L4, L6, and L8 representing the upper limits of the ranges illustrated in FIGS. 3 to 6.

Thus, the outline of the derivation process of the ranges illustrated in FIGS. 3 to 6 has been described.

### 2.3.2. Characteristic to be Satisfied)

As described above, in the derivation of FIGS. 3 to 6, the cases where the characteristic obtained by the simulation calculation satisfies the predetermined requirement are extracted. The predetermined requirement is as follows.

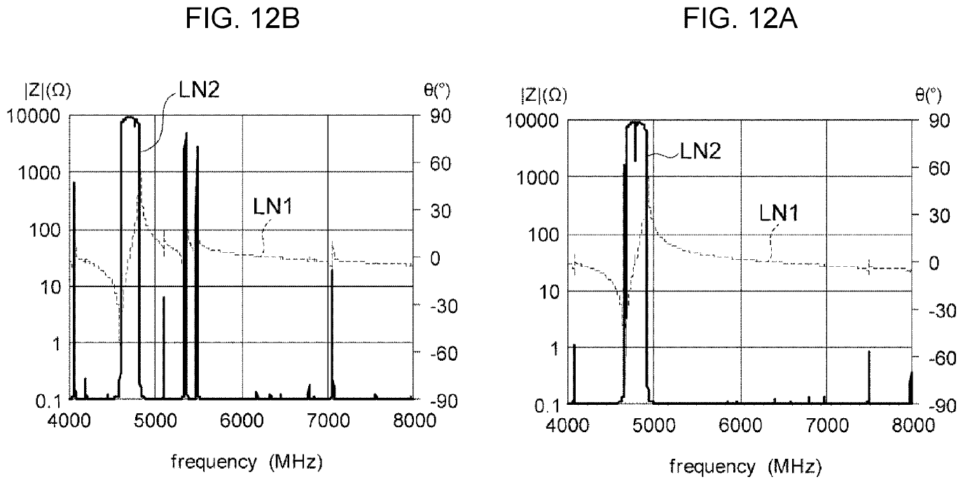

FIG. 12A is a diagram illustrating an example of the characteristic of the resonator 15. In FIG. 12A, the horizontal axis represents the frequency (MHz). The vertical axis on the left side represents an absolute value |Z| (Ω) of impedance. The vertical axis on the right side represents a phase θ(°) of the impedance. Line LN1 represents |Z| of the resonator 15. Line LN2 represents θ of the resonator 15.

As represented by line LN1, |Z| of the resonator 15 becomes a minimum at the resonance frequency (about 4700 MHz in the illustrated example) and becomes a maximum at the anti-resonance frequency (about 4900 MHz in the illustrated example). Furthermore, as represented by line LN2θ of the resonator 15 approaches 90° in a range between the resonance frequency and the anti-resonance frequency (referred to as a “first range” in this paragraph and the next paragraph) and approaches −90° outside the first range.

In general, the characteristic of the resonator 15 is better as θ approaches the 90° in the first range. Furthermore, the characteristic of the resonator 15 is better as θ approaches the −90° outside the first range. When spurious occurs outside the first range, θ separates from −90° (e increases).

In consideration of the relationship between the spurious and θ as described above, the above-described predetermined requirement is determined as follows: when the anti-resonance frequency is fa, in a range greater than or equal to fa and smaller than or equal to 1.5fa, θ of the resonator 15 is smaller than or equal to −60°. That is, the predetermined requirement is that the spurious is smaller on the high-frequency side relative to the anti-resonance frequency. In the procedure by which FIGS. 3 to 6 are actually obtained, the predetermined requirement is that, when fa is set to 5 GHz, θ of the resonator 15 is smaller than or equal to −60° in a range greater than or equal to 5 GHz and smaller than or equal to 7.5 GHZ. The value of 1.5 for 1.5fa and the value of-60° for 0 are set based on an empirical rule.

5 GHz as fa is a design value obtained with a comparatively simple calculation expression based on the pitch p, the velocity of the acoustic wave in the piezoelectric layer 11, the capacitance of the resonator 15, and the like. Accordingly, the anti-resonance frequency obtained by the simulation calculation in which influence of the parameters are considered as illustrated in FIGS. 3 to 6 may be shifted from 5 GHz as exemplified in FIG. 12A.

### (2.3.3. Conditions of Composite Substrate)

The configuration condition of the IDT electrode 19 illustrated in FIGS. 3 to 6 is derived based on a simulation result with respect to four forms. Regarding the four forms, the configuration of the composite substrate 3 differs from one form to another. Specifically, the forms are as follows.

In a first form, the piezoelectric layer 11 includes LT in the structure exemplified in FIG. 2. In a second form, LT is replaced with LN in the first form. In a third form, a multilayer film 39 (see FIG. 7A) is provided instead of the intermediate layer 9 (low-acoustic velocity film) in the first form. In a fourth form, a cavity 7a (see FIG. 7B) is provided instead of the intermediate layer 9 in the first form.

For each of the first to fourth cases, simulation calculation of an enormous number of cases is performed. For each of the first to fourth forms, the values of the various parameters are varied from each other as described above. Thus, for each of the forms, the upper limit values and the lower limit values on the vertical axis are obtained for values on the horizontal axis of FIGS. 3 to 6. An average value of the four forms is obtained for the lower limit values on the vertical axis for the values on the horizontal axis of FIGS. 3 to 6. Likewise, an average value of the four forms is obtained for the upper limit values on the vertical axis for the values on the horizontal axis of FIGS. 3 to 6. In addition, for the various values on the horizontal axis, an average value of the lower limit values on the vertical axis and an average value of the upper limit values on the vertical axis are obtained. An approximate line is obtained for the average values of the lower limit values on the vertical axis identified for the various values on the horizontal axis. This approximate line is the lines L1, L3, L5, and L7 representing the lower limits of the hatched regions of FIGS. 3 to 6. Likewise, an approximate line is obtained for the average values of the upper limit values on the vertical axis identified for the various values on the horizontal axis. This approximate line is the lines L2, L4, L6, and L8 representing the upper limits of the hatched regions of FIGS. 3 to 6.

FIG. 7A is a sectional view schematically illustrating a configuration of a composite substrate 3A of the third form including the multilayer film 39. The multilayer film 39 is made by, for example, alternately laminating a first acoustic film 39a and a second acoustic film 39b, which are different from each other in acoustic velocity and/or acoustic impedance. The acoustic velocity referred to herein may be, for example, as is the case with the acoustic velocities V1 and V2, an acoustic velocity of a bulk longitudinal wave and an acoustic velocity obtained with V (Young's modulus/density). The material of the first acoustic film 39a, the material of the second acoustic film 39b, the thickness of these films, and the number of films to be laminated may be appropriately set. Examples of the material of the first acoustic film 39a can include silicon dioxide (SiO₂). Examples of the material of the second acoustic film 39b can include tantalum pentoxide (Ta₂O₅), hafnium oxide (HfO₂), zirconium oxide (ZrO₂), and titanium oxide (TiO₂). A layer in contact with the piezoelectric layer 11 (the first acoustic film 39a in the illustrated example) may be different from the piezoelectric layer 11 in acoustic velocity and/or acoustic impedance.

FIG. 7B is a sectional view schematically illustrating a configuration of a composite substrate 3B of the fourth form including the cavity 7a. In FIG. 7B, the cavity 7a is realized by forming a recessed portion in an upper surface of the supporting substrate 7. The cavity 7a is, for example, superposed on the entirety of the resonator 15 (or 16) in perspective plan view. In the supporting substrate 7, the material of wall portions of the cavity 7a and the material of a layer included in a bottom surface of the cavity 7a may be the same or different.

In the description of the embodiment, for convenience, the reference numeral of the composite substrate 3 is used as a representative of various composite substrates such as composite substrates 3, 3A, and 3B. However, unless otherwise specified and unless inconsistency arises, in the description using the reference numeral of the composite substrate 3, the configuration of the composite substrate 3 may be understood as the configuration of the other composite substrates.

The above-described averaging is based on the fact that, even when the various conditions are changed, tendencies of the ranges illustrated in FIGS. 3 to 6 (from another viewpoint, the lower limit lines and the upper limit lines) are the same or similar to each other. An example of this fact is described below.

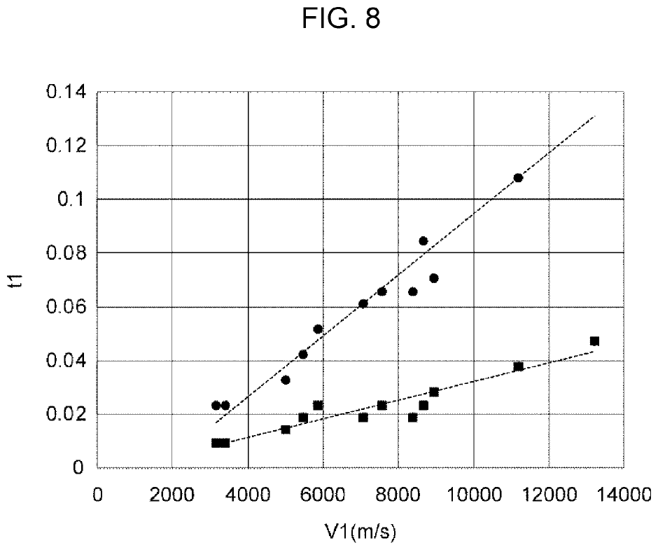

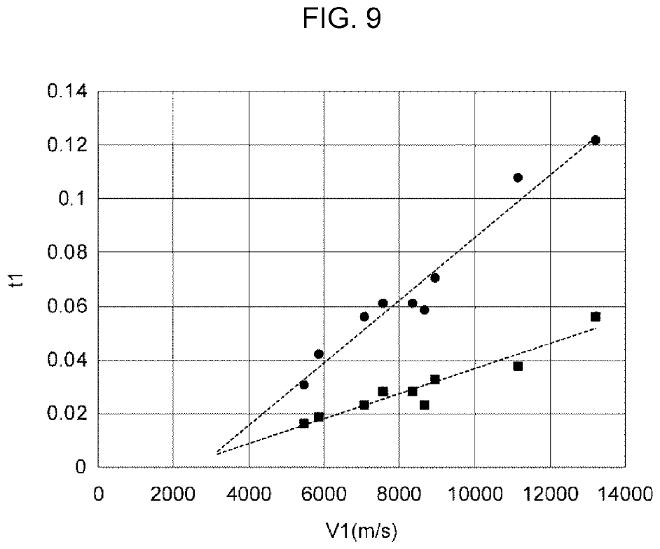

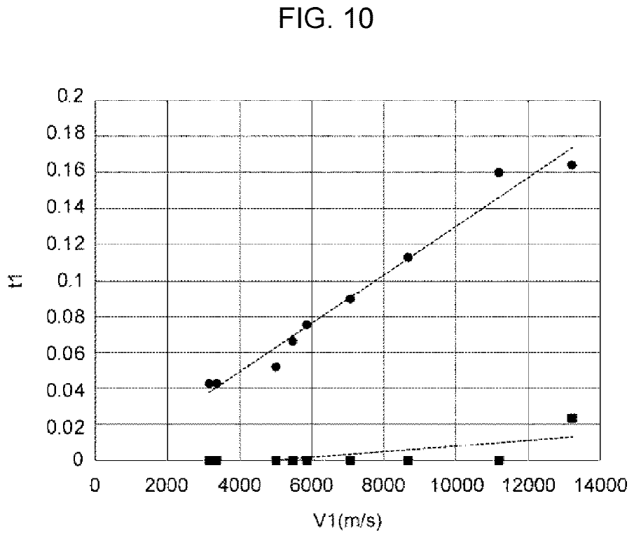

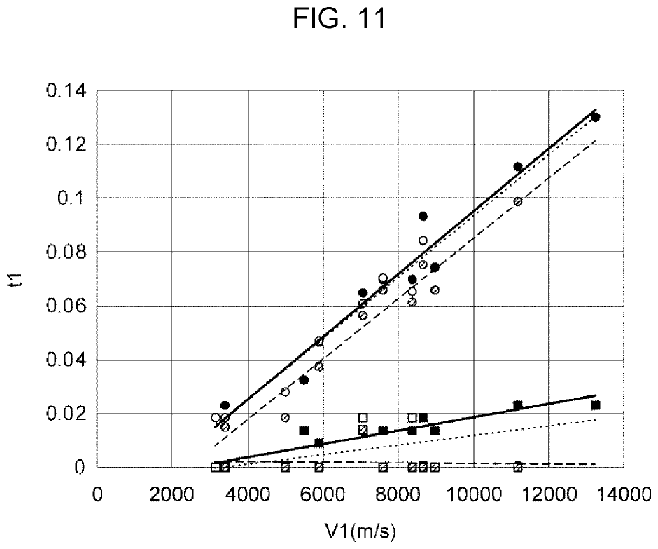

In each of FIGS. 8 to 11, the upper limit values and the lower limit values of the normalized thickness t1 for the various values of the acoustic velocity V1 are plotted. FIGS. 8 to 11 correspond to FIG. 3. FIG. 8 is related to the above-described first form. FIG. 9 is related to the above-described second form. FIG. 10 is related to the above-described third form. FIG. 11 illustrates results of three types with values of the pitch p being different from each other in the above-described first form. As can be understood from a comparison of FIGS. 8 to 11, even when the structure of the composite substrate 3 is changed and the pitch p is varied, in the relationship between the acoustic velocity V1 and the normalized thickness t1, ranges in which the phase θ on the high-frequency side of the anti-resonance frequency is smaller than or equal to −60° are substantially the same.

### (2.3.4. Acoustic Velocity of First Layer)

In FIGS. 3 to 6, the acoustic velocity V1 of the first layer (first conductor layer 35) is the parameter. An example of the grounds of the validity of this is described as follows.

As has been described, FIG. 12A is a diagram illustrating an example of the characteristic of the resonator 15. In more detail, the characteristic illustrated in FIG. 12A is obtained by the simulation calculation. In this simulation calculation, the first conductor layer 35 is CuAl₂ having a thickness of 0.1 μm, and the second conductor layer 37 is Al having a thickness of 0.1 μm.

FIG. 12B is a diagram illustrating, similarly to FIG. 12A, the characteristic of the resonator 15 obtained by the simulation calculation. The simulation conditions related to FIG. 12B are the same as the simulation conditions related to FIG. 12A other than that the materials of the first conductor layer 35 and the second conductor layer 37 are reversed. For confirmation, the layers and the materials are described as follows: in the simulation calculation related to FIG. 12B, the first conductor layer 35 is Al having a thickness of 0.1 μm, and the second conductor layer 37 is CuAl₂ having a thickness of 0.1 μm.

As can be understood from a comparison between FIGS. 12A and 12B, when the materials of the first conductor layer 35 and the second conductor layer 37 are reversed, the characteristic of the resonator 15 varies. For example, spurious in which θ exceeds −60° occurs between 5 to 7.5 GHz in FIG. 12B, while this spurious does not occur in FIG. 12A.

From this, it is understood that, for example, even when the configuration condition of the IDT electrode 19 is defined based on the total thickness of the first conductor layer 35 and the second conductor layer 37 and/or an average acoustic velocity of the entirety of the first conductor layer 35 and the second conductor layer 37, the spurious on the high-frequency side is not necessarily able to be reduced. As proposed in the embodiment, when the first conductor layer 35 and the second conductor layer 37 are independently considered, the probability of reducing the spurious increases.

### 3. Other Examples of Electrode

FIGS. 13A to 13E are diagrams illustrating other examples of the laminated structure of the electrode layer 5 (IDT electrode 19).

As illustrated in FIG. 13A, the elastic wave element 1 may include an insulative protective film 41 that covers the upper surface of the piezoelectric layer 11 from an upper side of one or more metal layers (the first conductor layer 35 and the second conductor layer 37 in the illustrated example). Although the protective film 41 does not cover side surfaces of the metal layers in the illustrated example, the protective film 41 may cover the side surfaces of the metal layers. The protective film 41 contributes to, for example, reducing corrosion of the metal layers. Examples of the material of the protective film 41 include SiO₂ and Si3N₄.

In the example of FIG. 13A, the thickness of the protective film 41 is comparatively small. For example, the thickness of the protective film 41 may be smaller than or equal to 150 Å. From another viewpoint, the thicknesses of the protective film 41 may be smaller than each of the thickness of the first layer (first conductor layer 35) and the thickness of the second layer (second conductor layer 37). Conversely, each of the thickness of the first layer and the thickness of the second layer may be, for example, greater than 150 Å. The thickness of the protective film 41 may be, for example, smaller than or equal to ⅓ or smaller than or equal to ⅕ of the thickness of the first layer or the thickness of the second layer.

When such a comparatively thin protective film 41 is provided, the thickness of the protective film 41 on the metal layers (the first conductor layer 35 and the second conductor layer 37) is not necessarily considered with respect to the thickness of the IDT electrode 19. The reason for this is that influence of the protective film 41 exerted on spurious is small. Accordingly, for example, the normalized thickness t1 of the first layer may be a thickness obtained by normalizing a thickness t01 from the upper surface of the piezoelectric layer 11 to an upper surface of the first layer. The normalized thickness t2 of the second layer may be a thickness obtained by normalizing a thickness t02 from the upper surface of the first layer to an upper surface of the second layer (a lower surface of the protective film 41).

In examples of FIGS. 13B and 13C, as is the case with the example illustrated in FIG. 13A, the protective film 41 is provided. However, unlike the example of FIG. 13A, the protective film 41 is comparatively thick. Furthermore, from another viewpoint, the material of the second layer superposed on the first layer (first conductor layer 35) is the same as the material of the protective film 41. For convenience, the structures of FIGS. 13B and 13C are understood as the superposition of the protective film 41 on the first layer in the description herein.

The comparatively thick protective film 41 as described above may contribute to, in addition to the protection of the metal layer from corrosion, compensation for characteristic variation of the resonator 15 caused by temperature variation. The thickness of the comparatively thick protective film 41 may be, although it is described conversely to the comparatively thin protective film 41, for example, greater than 150 Å. Furthermore, for example, the thickness of the comparatively thick protective film 41 may be greater than ⅓, ½, or 1 of the thickness of the first layer.

The comparatively thick protective film 41 can exert influence on spurious. Accordingly, the comparatively thick protective film 41 may be considered as the entirety (the illustrated examples) or part of the second layer superposed on the first layer. For example, in the illustrated examples, the normalized thickness t2 of the second layer may be a thickness obtained by normalizing the thickness t02 (thickness t02 of the protective film 41) from the upper surface of the first layer to an upper surface of the IDT electrode 19 (an upper surface of the protective film 41).

In an example of FIG. 13D, an adhesion layer 43 is interposed between the piezoelectric layer 11 and the first conductor layer 35. The adhesion layer 43 contributes to, for example, improvement of joining strength between the piezoelectric layer 11 and the first conductor layer 35. The adhesion layer 43 is, for example, a conductor layer (metal layer). The adhesion layer 43 is comparatively thin. For example, the thickness of the adhesion layer 43 may be smaller than or equal to 100 Å. From another viewpoint, the thicknesses of the adhesion layer 43 may be smaller than the thickness of the first conductor layer 35. Conversely, the thickness of the first conductor layer 35 may be, for example, greater than 100 Å. The thickness of the adhesion layer 43 may be, for example, smaller than or equal to ⅓ or smaller than or equal to ⅕ of the thickness of the first conductor layer 35. The material of the adhesion layer 43 is arbitrary and may be, for example, Ti.

When such a comparatively thin adhesion layer 43 is provided, the thickness of the adhesion layer 43 is not necessarily considered with respect to the thickness of the IDT electrode 19. From another viewpoint, the adhesion layer 43 is not an example of the first layer, and the first conductor layer 35 superposed on the adhesion layer 43 is the example of the first layer. The reason for this is that influence of the adhesion layer 43 exerted on spurious is small. Accordingly, for example, the normalized thickness t1 of the first layer may be a thickness obtained by normalizing the thickness t01 from an upper surface of the adhesion layer 43 (a lower surface of the first conductor layer 35) to the upper surface of the first conductor layer 35.

Furthermore, in the example of FIG. 13D, two or more layers the materials of which are different from each other (a first configuration layer 37A and a second configuration layer 37B in the illustrated example) are provided on the first layer (first conductor layer 35). In this case, the entirety of these two or more layers may be understood as the second layer. Herein, as has been described, the comparatively thin protective film 41 is not included in the second layer. From another viewpoint, the normalized thickness t2 of the second layer may be a thickness obtained by normalizing the thickness t02 from the upper surface of the first layer to a lower surface of the protective film 41 (an upper surface of the second configuration layer 37B).

The materials of the first configuration layer 37A and the second configuration layer 37B may be conductors (for example, metal) or insulators. Furthermore, regarding the materials of the first layer (first conductor layer 35) and the two or more layers included in and the second layer (the first configuration layer 37A and the second configuration layer 37B), the layers made of the same material may exist as long as the materials of the layers adjacent to each other are different from each other. For example, in the illustrated example, the material of the first conductor layer 35 and the material of the second configuration layer 37B may be the same.

When the second layer includes two or more types of materials, an average acoustic velocity may be used as the acoustic velocity V2 of the second layer. The average acoustic velocity may be calculated by, for example, adding up values obtained by multiplying the acoustic velocities of layers by ratios of the layers in thickness to the thickness of the second layer. When the thicknesses of the layers are not fixed, ratios in volume of the layers may be used instead of the ratios of the layers in thickness. Although the above description is related to the acoustic velocity V2, this is similarly applied to the density p of the second layer. That is, an average density may be used as the density p of the second layer, and ratios in thickness or volume may be used to calculate the average density.

In an example of FIG. 13E, the entirety of the IDT electrode 19 includes the first conductor layer 35 other than the comparatively thin protective film 41. Such a case may be understood as a case where only the first layer is provided while the second layer is not provided. The normalized thickness t1 of the first layer may be a thickness obtained by normalizing the thickness t01 of the first layer. Furthermore, although the third layer has been described as a combination of the first layer and the second layer in the embodiment, the first layer may be understood as the third layer when the second layer is not provided. That is, the normalized thickness t1 and the normalized thickness t3 may be the same.

From various laminated structures of the IDT electrode 19 (electrode layer 5) having been exemplified above, the first layer and the second layer for which the normalized thicknesses t1 and t2 are obtained can be described as follows.

The IDT electrode 19 at least includes the first layer (first conductor layer 35) including the first material having conductivity. In other words, the IDT electrode 19 does not necessarily include the second layer (FIG. 13E). The first layer has a thickness greater than 100 Å. Furthermore, the first layer is directly superposed on the piezoelectric layer 11 (FIGS. 2, 13A to 13C, and 13E). Alternatively, the first layer is superposed on the piezoelectric layer 11 with the metal layer (adhesion layer 43) of smaller than or equal to 100 Å interposed therebetween (FIG. 13D). The metal layer is in contact with the piezoelectric layer 11 and the first layer.

The IDT electrode 19 may include an upper structure that is superposed on the upper surface of the first layer (first conductor layer 35) and includes one or more types of materials different from the first material (FIGS. 2 and 13A to 13E). When the above-described upper structure includes an insulating layer (the thin protective film 41) of smaller than or equal to 150 Å included in the upper surface of the IDT electrode 19 (FIGS. 13A, 13D, and 13E), a portion between the upper surface of the first layer and a lower surface of the insulating layer may be the second layer. Since such a second layer is unable to be defined in the example of FIG. 13E, the second layer is not provided in the example of FIG. 13E. When the above-described upper structure does not include the above-described insulating layer (the thin protective film 41; FIGS. 2, 13B, and 13C), a portion between the upper surface of the first layer and the upper surface of the IDT electrode 19 may be the second layer. The second layer may have a thickness greater than 150 Å.

When the IDT electrode 19 includes the insulating layer (the thin protective film 41) of smaller than or equal to 150 Å included in the upper surface of the IDT electrode 19 (FIGS. 13A, 13D, and 13E), a portion between a lower surface of the first layer (for example, the first conductor layer 35) and the lower surface of the thin protective film 41 may be the third layer. When the IDT electrode 19 does not include the thin protective film 41 (FIGS. 2, 13B, and 13C), a portion between the lower surface of the first conductor layer 35 and the upper surface of the IDT electrode 19 may be the third layer. The third layer may include a combination of the first layer and the second layer (FIGS. 2, and 3A to 3D) or only the first layer (FIG. 13E).

Various laminated structures of the IDT electrode 19 can be used other than the illustrated laminated structures. Also in those cases, the first layer and the second layer may be identified based on the description of the first layer and the second layer as described above.

### 4. Splitter

FIG. 14 is a circuit diagram schematically illustrating a configuration of a splitter 101 as an example of utilization of the elastic wave element 1. As can be understood from reference numerals indicated at the upper left of the page of FIG. 14, the comb-shaped electrodes 23 are schematically illustrated in FIG. 14 by using a fork shape including two prongs, and the reflectors 21 are represented by a single line including bends at both ends.

The splitter 101 includes, for example, a transmission filter 109 and a reception filter 111. The transmission filter 109 is configured to filter a transmission signal from a transmission terminal 105 and output the filtered signal to an antenna terminal 103. The reception filter 111 is configured to filter a reception signal from the antenna terminal 103 and output the filtered signal to a pair of reception terminals 107. That is, the splitter 101 is configured as a duplexer.

The transmission filter 109 includes, for example, a ladder filter including a plurality of resonators 15 connected in a ladder shape. That is, the transmission filter 109 includes the plurality of resonators 15 (series resonators) or a single resonator 15 connected in series between the transmission terminal 105 and the antenna terminal 103 and a plurality of resonators 15 (parallel arm, parallel resonator) or a single resonator 15 connecting the series line (a series arm) and the reference potential. The plurality of resonators 15 included in the transmission filter 109 are, for example, provided on the same composite substrate 3.

The reception filter 111 includes, for example, the resonator 15 and a multi-mode filter (including a double-mode type filter) 113. The multi-mode filter 113 includes a plurality of (three in the illustrated example) IDT electrodes 19 (from another viewpoint, the resonator 16, the reference numeral is omitted herein) and a pair of reflectors 21. The plurality of IDT electrodes 19 are arranged in the propagation direction of the acoustic wave. The pair of reflectors 21 are disposed on both sides of the IDT electrodes 19. The resonator 15 and the multi-mode filter 113 included in the reception filter 111 are, for example, provided on the same composite substrate 3.

The transmission filter 109 and the reception filter 111 may be provided on the same composite substrate 3 or provided on composite substrates 3 different from each other. FIG. 14 is merely the example of the configuration of the splitter 101. For example, as is the case with the transmission filter 109, the reception filter 111 may include a ladder filter. Furthermore, out of the series resonators and the parallel resonator included in the single ladder filter, the series resonators may be provided on one composite substrate 3 and the parallel resonator may be provided on the other composite substrate 3. The splitter 101 (multiplexer) is not limited to the duplexer. For example, the splitter may be a diplexer or a device including three or more filters (for example, a triplexer or a quadplexer). Unlike the above description, various filters or the splitter 101 may be understood as the elastic wave element 1.

### 5. Communication Device

FIG. 15 is a block diagram illustrating a main part of a communication device 151 as an example of utilization of the elastic wave element 1 (splitter 101). The communication device 151 includes a module 171 and a housing 173 in which the module 171 is accommodated. The module 171 is configured to perform wireless communication utilizing a radio wave and includes the splitter 101.

In the module 171, a radio frequency-integrated circuit (RF-IC) 153 (an example of an integrated circuit) modulates a transmission information signal TIS including information to be transmitted and increases the frequency of the transmission information signal TIS (converts the carrier wave frequency into a radio frequency signal). Thus, the transmission information signal TIS is changed into a transmission signal TS. An unnecessary component other than the pass band for transmission is removed from the transmission signal TS by a band pass filter 155 and the transmission signal TS is amplified by an amplifier 157. This transmission signal TS is input to the splitter 101 (transmission terminal 105). The splitter 101 (transmission filter 109) is configured to remove an unnecessary component other than the pass band for transmission from the input transmission signal TS and output, from the antenna terminal 103 to an antenna 159, the transmission signal TS after the removal. The antenna 159 is configured to convert the input electrical signal (transmission signal TS) into a wireless signal (radio wave) and transmit the wireless signal.

Also in the module 171, a wireless signal (radio wave) received by the antenna 159 is converted into an electrical signal (reception signal RS) by the antenna 159 and input to the splitter 101 (antenna terminal 103). The splitter 101 (reception filter 111) is configured to remove an unnecessary component other than the pass band for reception from the input reception signal RS and output, from the reception terminal 107 to an amplifier 161, the reception signal RS. The output reception signal RS is amplified by the amplifier 161, and an unnecessary component other than the pass band for reception is removed from the reception signal RS by a band pass filter 163. The RF-IC 153 is configured to reduce the frequency of the reception signal RS and demodulate the reception signal RS. Thus, the reception signal RS is changed into a reception information signal RIS.

The transmission information signal TIS and the reception information signal RIS may be low-frequency signals (baseband signals) including appropriate information and are, for example, analog audio signals or digitized audio signals. The pass band of the wireless signal may be appropriately set. According to the present embodiment, a pass band of a comparatively high frequency (for example, higher than or equal to 3 GHz or higher than or equal to 5 GHz) is possible. The modulation method is one selected from the group consisting of phase modulation, amplitude modulation, and frequency modulation, or a combination of two or more selected from the group consisting of phase modulation, amplitude modulation, and frequency modulation. Although the circuit method is exemplified by a direct conversion method in FIG. 15, the circuit method may be an appropriate method other than the direct conversion method. For example, the circuit method may be a double superheterodyne method. FIG. 15 schematically illustrates only the main part. A low-pass filter, an isolator, and the like may be added at an appropriate positions, or the positions of the amplifiers or the like may be changed.

The module 171 includes, for example, the components from the RF-IC 153 to the antenna 159 on the same circuit substrate. That is, the elastic wave element 1 (part or the entirety of the splitter 101) is combined with the other components and modularized. The elastic wave element 1 may be included in the communication device 151 without being modularized. The components exemplified as the components of the module 171 may be positioned outside the module and are not necessarily accommodated in the housing 173. For example, the antenna 159 may be exposed to the outside of the housing 173.

### 6. Summarization of Embodiment

As has been described, the elastic wave element 1 according to the present embodiment includes the supporting substrate 7, the piezoelectric layer 11 positioned on the supporting substrate 7, and the IDT electrode 19 positioned on the piezoelectric layer 11. The IDT electrode 19 includes the first layer (first conductor layer 35) including the first material having conductivity. The first conductor layer 35 has a thickness greater than 100 Å. Furthermore, the first conductor layer 35 is superposed on the piezoelectric layer 11 directly or with the metal layer (adhesion layer 43) of smaller than or equal to 100 Å interposed therebetween. The metal layer is in contact with the piezoelectric layer 11 and the first conductor layer 35. When the pitch of the electrode fingers 27 of the IDT electrode 19 is p (μm) and the value obtained by dividing the thickness of the first conductor layer 35 (μm) by 2p^{0.101} is the normalized thickness t1, the normalized thickness t1 and the acoustic velocity V1 (m/s) of the bulk longitudinal wave propagating through the first material satisfy the following expression:

$$2.14 \times 1 {0}^{- 6} V 1 - 1.16 \times 1 {0}^{- 2} < t 1 < 1.17 \times 1 {0}^{- 5} V 1 - 1.63 \times 1 {0}^{- 2} .$$

That is, the normalized thickness t1 and the acoustic velocity V1 fall within the hatched region of in FIG. 3.

In this case, as clearly understood from the derivation process of the hatched region of FIG. 3, ease of reduction of the spurious is increased on the high-frequency side relative to the anti-resonance frequency. As has been described with reference to FIGS. 12A and 12B, attention is focused on the acoustic velocity and the thickness of the first layer instead of the acoustic velocity and the thickness of the entirety of the IDT electrode 19. This enables reduction of the spurious not achieved only by focusing attention on the acoustic velocity and the thickness of the entirety of the IDT electrode 19. Furthermore, normalization is performed not with M (=2p) but with α(=2p^{0.101}) obtained from the relationship between the resonance frequency and the acoustic velocity of the IDT electrode 19. This facilitates maintaining of the effect of reducing the spurious when applied to the elastic wave element 1 of a different resonance frequency.

There are parameters exerting influence on spurious other than the normalized thickness t1 and the acoustic velocity V1 used in FIG. 3. Thus, the fact that the normalized thickness t1 and the acoustic velocity V1 fall within the hatched region of FIG. 3 does not necessarily ensure the characteristic (the phase θ of the spurious on the high-frequency side of the anti-resonance frequency is smaller than or equal to −60°) used as the reference in the derivation process of FIG. 3. However, as long as the other parameters fall within a practical range, the tendency of the influence of the normalized thickness t1 and the acoustic velocity V1 exerted on the spurious on the high-frequency side is the same. Accordingly, even when the other parameters are arbitrary values, ease of reduction of the spurious on the high-frequency side of the anti-resonance frequency is still increased with the normalized thickness t1 and the acoustic velocity V1 falling within the hatched region of FIG. 3. From another viewpoint, although a best effect is not necessarily obtained, ease of obtaining a better effect is increased.

From another viewpoint, the elastic wave element 1 according to the present embodiment includes the supporting substrate 7, the piezoelectric layer 11 positioned on the supporting substrate 7, and the IDT electrode 19 positioned on the piezoelectric layer 11. The IDT electrode 19 includes the first layer (first conductor layer 35) including the first material having conductivity and an upper structure (for example, the second conductor layer 37) that is superposed on the upper surface of the first conductor layer 35 and includes one or more types of materials different from the first material. The first conductor layer 35 has a thickness greater than 100 Å. Furthermore, the first conductor layer 35 is superposed on the piezoelectric layer 11 directly or with the metal layer (adhesion layer 43) of smaller than or equal to 100 Å interposed therebetween. The metal layer is in contact with the piezoelectric layer 11 and the first conductor layer 35. When the above-described upper structure includes the insulating layer (the thin protective film 41) of a thickness smaller than or equal to 150 Å included in the upper surface of the IDT electrode 19, the portion between the upper surface of the first conductor layer 35 and the lower surface of the thin protective film 41 is the second layer. When the above-described upper structure does not include the thin protective film 41, the portion between the upper surface of the first conductor layer 35 and the upper surface of the IDT electrode 19 is the second layer. The second layer (for example, the second conductor layer 37) has a thickness greater than 150 Å. When the pitch of the electrode fingers 27 of the IDT electrode 19 is p (μm) and the value obtained by dividing the thickness of the second layer (μm) by 2p^{0.101} is the normalized thickness t2, the normalized thickness t2 and the acoustic velocity V1 (m/s) of the bulk longitudinal wave propagating through the first material satisfy the following expression:

4.77×10⁻⁶V1−1.18×10⁻²<t2<2.52×10⁻⁶V1+4.09×10⁻².

That is, the normalized thickness t2 and the acoustic velocity V1 fall within the hatched region of FIG. 4.

In this case, as clearly understood from the derivation process of the hatched region of FIG. 4, ease of reduction of the spurious is increased on the high-frequency side relative to the anti-resonance frequency. The effect produced by causing the normalized thickness t1 and the acoustic velocity V1 to fall within the hatched region of FIG. 3 has already been described. This description may be incorporated in the description of the effect produced by causing the normalized thickness t2 and the acoustic velocity V2 to fall within the hatched region of FIG. 4 by, for example, replacing the terms normalized thickness t1 with the terms normalized thickness t2.

From still another viewpoint, the elastic wave element 1 according to the present embodiment includes the supporting substrate 7, the piezoelectric layer 11 positioned on the supporting substrate 7, and the IDT electrode 19 positioned on the piezoelectric layer 11. The IDT electrode 19 includes the first layer (first conductor layer 35) including the first material having conductivity and an upper structure (for example, the second conductor layer 37) that is superposed on the upper surface of the first conductor layer 35 and includes one or more types of materials different from the first material. The first conductor layer 35 has a thickness greater than 100 Å. Furthermore, the first conductor layer 35 is superposed on the piezoelectric layer 11 directly or with the metal layer (adhesion layer 43) of smaller than or equal to 100 Å interposed therebetween. The metal layer is in contact with the piezoelectric layer 11 and the first conductor layer 35. When the above-described upper structure includes the insulating layer (the thin protective film 41) that is included in the upper surface of the IDT electrode 19 and that has a thickness smaller than or equal to 150 Å, the portion between the upper surface of the first conductor layer 35 and the lower surface of the thin protective film 41 is the second layer. When the above-described upper structure does not include the thin protective film 41, the portion between the upper surface of the first conductor layer 35 and the upper surface of the IDT electrode 19 is the second layer. The second layer (for example, the second conductor layer 37) has a thickness greater than 150 Å. The average density ρ (g/cm³) of the second layer and the average acoustic velocity V2 (m/s) of the bulk longitudinal wave propagating through the second layer satisfy the following expression.

$$- 135.64 ρ + 4155.6 < V 2 < - 2470.1 ρ + 16872.$$

That is, the density p and the acoustic velocity V2 fall within the hatched region of FIG. 6.

In this case, as clearly understood from the derivation process of the hatched region of FIG. 6, ease of reduction of the spurious is increased on the high-frequency side relative to the anti-resonance frequency. The effect produced by causing the normalized thickness t1 and the acoustic velocity V1 to fall within the hatched region of FIG. 3 has already been described. This description may be incorporated in the description of the effect produced by causing the density p and the acoustic velocity V2 to fall within the hatched region of FIG. 6 by, for example, replacing the terms normalized thickness t1 and the acoustic velocity V1 with the terms density p and the acoustic velocity V2.

Furthermore, in the present embodiment, when the IDT electrode 19 includes the insulating layer (the thin protective film 41) of smaller than or equal to 150 Å included in the upper surface of the IDT electrode 19, the portion between the lower surface of the first layer (for example, the first conductor layer 35) and the lower surface of the thin protective film 41 may be the third layer (for example, the combination of the first layer and the second layer). When the IDT electrode 19 does not include the thin protective film 41, the portion between the lower surface of the first conductor layer 35 and the upper surface of the IDT electrode 19 is the third layer. The third layer may have a thickness greater than 150 Å. When a value obtained by dividing the thickness (μm) of the third layer by 2p^{0.101} is the normalized thickness t3, the following expression may be satisfied.

$$6.91 \times 1 {0}^{- 6} V 1 - 2.34 \times 1 {0}^{- 2} < t 3 < 1.44 \times 1 {0}^{- 5} V 1 + 2.45 \times 1 {0}^{- 2} .$$

That is, the normalized thickness t3 and the acoustic velocity V1 may fall within the hatched region of FIG. 5.

In this case, as clearly understood from the derivation process of the hatched region of FIG. 5, ease of reduction of the spurious is increased on the high-frequency side relative to the anti-resonance frequency. The effect produced by causing the normalized thickness t1 and the acoustic velocity V1 to fall within the hatched region of FIG. 3 has already been described. This description may be incorporated in the description of the effect produced by causing the normalized thickness t3 and the acoustic velocity V1 to fall within the hatched region of FIG. 5 by, for example, replacing the terms normalized thickness t1 with the terms normalized thickness t3.

The thickness of the piezoelectric layer 11 may be smaller than or equal to 2p.

In this case, for example, ease of utilization of a plate wave of a comparatively high velocity is increased. As a result, for example, ease of realization of the elastic wave element 1 of a high resonance frequency is increased. For example, in the elastic wave element 1 in which the pitch p is about 1 μm, a resonance frequency of higher than or equal to 3 GHz or higher than or equal to 5 GHz can be realized. Furthermore, in the derivation of FIGS. 3 to 6, simulation assuming the elastic wave element 1 of such a superhigh frequency is performed. Thus, the effect to be produced by causing the values of the various parameters to fall within the ranges indicated in FIGS. 3 to 6 is likely to be produced.

The material of the piezoelectric layer 11 may be lithium tantalate or lithium niobate. The cavity 7a or at least one acoustic film (for example, the intermediate layer 9 or the multilayer film 39 (the first acoustic film 39a and the second acoustic film 39b)) different from the piezoelectric layer 11 in acoustic velocity (and/or acoustic impedance) may be interposed between the piezoelectric layer 11 and the supporting substrate 7 in a region superposed on the IDT electrode 19 in perspective plan view.

In this case, for example, energy of the acoustic wave is likely to be confined within the piezoelectric layer 11, and the insertion loss is reduced. Furthermore, in the derivation of FIGS. 3 to 6, simulation assuming that the elastic wave element 1 includes the intermediate layer 9 (low-acoustic velocity film), the multilayer film 39, or the cavity 7a is performed. Thus, the effect to be produced by causing the values of the various parameters to fall within the ranges indicated in FIGS. 3 to 6 is likely to be produced.

The technique related to the present disclosure is not limited to the above-described embodiment but may be carried out in various forms.

For example, the composite substrate may include the following two layers between the supporting substrate and the piezoelectric layer: a high-acoustic velocity film superposed on the supporting substrate and a low-acoustic velocity film superposed on the high-acoustic velocity film. The composite substrate may include a single high-acoustic velocity film between the supporting substrate and the piezoelectric layer. In the composite substrate, the piezoelectric layer and the supporting substrate may be directly joined to each other in a region containing the IDT electrode in a perspective plan view. The composite substrate may only include, between the piezoelectric layer and the supporting substrate, a joining layer having a degree of thickness with which acoustic influence is hardly exerted on the acoustic wave propagating through the piezoelectric layer. Such a joining layer may be understood as a layer different from the intermediate layer that has already been described and that has the acoustic velocity (and/or the acoustic impedance) different from the acoustic velocity (and/or the acoustic impedance) of the piezoelectric layer. The thickness of the joining layer may be, for example, smaller than or equal to 0.005λ or smaller than or equal to 0.001λ.

### REFERENCE SIGNS

1 elastic wave element
7 supporting substrate
11 piezoelectric layer
19 IDT electrode
27 electrode finger (of IDT electrode)
35 first conductor layer (first layer)

1. An elastic wave element comprising:
a supporting substrate;
a piezoelectric layer positioned on the supporting substrate; and
an interdigital transducer electrode positioned on the piezoelectric layer,
wherein the interdigital transducer electrode includes a first layer including a first material having conductivity,
wherein the first layer has a thickness greater than 100 Å,
wherein the first layer is superposed on the piezoelectric layer directly or with a metal layer of smaller than or equal to 100 Å interposed between the first layer and the piezoelectric layer, the metal layer being in contact with the first layer and the piezoelectric layer, and
wherein, when a pitch of electrode fingers of the interdigital transducer electrode is p (μm) and a value obtained by dividing a thickness of the first layer (μm) by 2p^{0.101} is a normalized thickness t1, the normalized thickness t1 and an acoustic velocity V1 (m/s) of a bulk longitudinal wave propagating through the first material satisfy an expression below:
$$2.14 \times 1 {0}^{- 6} V 1 - 1.16 \times 1 {0}^{- 2} < t 1 < 1.17 \times 1 {0}^{- 5} V 1 - 1.63 \times 1 {0}^{- 2} .$$

2. The elastic wave element according to claim 1,
wherein the interdigital transducer electrode further includes an upper structure that is superposed on an upper surface of the first layer and that includes one or more types of materials different from the first material,
wherein, when the upper structure includes an insulating layer of smaller than or equal to 150 Å included in an upper surface of the interdigital transducer electrode, a portion between the upper surface of the first layer and a lower surface of the insulating layer is a second layer,
wherein, when the upper structure does not include the insulating layer, a portion between the upper surface of the first layer and the upper surface of the interdigital transducer electrode is the second layer,
wherein the second layer has a thickness greater than 150 Å, and
wherein, when a value obtained by dividing the thickness (μm) of the second layer by 2p^{0.101} is a normalized thickness t2, an expression below is satisfied:
$$4.77 \times 1 {0}^{- 6} V 1 - 1.18 \times 1 {0}^{- 2} < t 2 < 2.52 \times 1 {0}^{- 6} V 1 + 4.09 \times 1 {0}^{- 2} .$$

3. An elastic wave element comprising:
a supporting substrate;
a piezoelectric layer positioned on the supporting substrate; and
an interdigital transducer electrode positioned on the piezoelectric layer,
wherein the interdigital transducer electrode includes
a first layer including a first material having conductivity, and
an upper structure that is superposed on an upper surface of the first layer and that includes one or more types of materials different from the first material,
wherein the first layer has a thickness greater than 100 Å,
wherein the first layer is superposed on the piezoelectric layer directly or with a metal layer of smaller than or equal to 100 Å interposed between the first layer and the piezoelectric layer, the metal layer being in contact with the first layer and the piezoelectric layer, and
wherein, when the upper structure includes an insulating layer of a thickness smaller than or equal to 150 Å included in an upper surface of the interdigital transducer electrode, a portion between the upper surface of the first layer and a lower surface of the insulating layer is a second layer,
wherein when the upper structure does not include the insulating layer, a portion between the upper surface of the first layer and the upper surface of the interdigital transducer electrode is the second layer,
wherein the second layer has a thickness greater than 150 Å, and
wherein, when a pitch of electrode fingers of the interdigital transducer electrode is p (μm) and a value obtained by dividing the thickness of the second layer (μm) by 2p^{0.101} is a normalized thickness t2, the normalized thickness t2 and an acoustic velocity V1 (m/s) of a bulk longitudinal wave propagating through the first material satisfy an expression below:
$$4.77 \times 1 {0}^{- 6} V 1 - 1.18 \times 1 {0}^{- 2} < t 2 < 2.52 \times 1 {0}^{- 6} V 1 + 4.09 \times 1 {0}^{- 2} .$$

4. The elastic wave element according to claim 2,
wherein an average density ρ (g/cm³) of the second layer and an average acoustic velocity V2 (m/s) of a bulk longitudinal wave propagating through the second layer satisfy an expression below:
$$- 135.64 ρ + 4155.6 < V 2 < - 2470.1 ρ + 16872.$$

5. An elastic wave element comprising:
a supporting substrate;
a piezoelectric layer positioned on the supporting substrate; and
an interdigital transducer electrode positioned on the piezoelectric layer,
wherein the interdigital transducer electrode includes
a first layer including a first material having conductivity, and
an upper structure that is superposed on an upper surface of the first layer and that includes one or more types of materials different from the first material,
wherein the first layer
has a thickness greater than 100 Å and
wherein the first layer is superposed on the piezoelectric layer directly or with a metal layer of smaller than or equal to 100 Å interposed between the first layer and the piezoelectric layer, the metal layer being in contact with the first layer and the piezoelectric layer,
wherein, when the upper structure includes an insulating layer of a thickness smaller than or equal to 150 Å included in an upper surface of the interdigital transducer electrode, a portion between the upper surface of the first layer and a lower surface of the insulating layer is a second layer,
wherein when the upper structure does not include the insulating layer, a portion between the upper surface of the first layer and the upper surface of the interdigital transducer electrode is the second layer,
wherein the second layer has a thickness greater than 150 Å, and
wherein an average density ρ (g/cm³) of the second layer and an average acoustic velocity V2 (m/s) of a bulk longitudinal wave propagating through the second layer satisfy an expression below:
$$- 135.64 ρ + 4155.6 < V 2 < - 2470.1 ρ + 16872.$$

6. The elastic wave element according to claim 1,
wherein, when the interdigital transducer electrode includes an insulating layer of smaller than or equal to 150 Å included in an upper surface of the interdigital transducer electrode, a portion between a lower surface of the first layer and a lower surface of the insulating layer is a third layer,
wherein, when the interdigital transducer electrode does not include the insulating layer, a portion between the lower surface of the first layer and the upper surface of the interdigital transducer electrode is the third layer,
wherein, the third layer has a thickness greater than 150 Å, and
wherein, when a value obtained by dividing the thickness (μm) of the third layer by 2p^{0.101} is a normalized thickness t3, an expression below is satisfied:
6.91×10⁻⁶V1−2.34×10⁻²<3<1.42×10⁻⁵V1+2.45×10⁻².

7. The elastic wave element according to claim 1,
wherein, when the pitch of the electrode fingers of the interdigital transducer electrode is p (μm), a thickness of the piezoelectric layer is smaller than or equal to 2p.

8. The elastic wave element according to claim 1,
wherein a material of the piezoelectric layer is lithium tantalate or lithium niobate, and
wherein a cavity or at least one acoustic film having a different acoustic velocity from an acoustic velocity of the piezoelectric layer is interposed between the piezoelectric layer and the supporting substrate in a region superposed on the interdigital transducer electrode in perspective plan view.

9. The elastic wave element according to claim 1,
wherein a Lamb wave in an A1 mode in the piezoelectric layer is utilized.

10. The elastic wave element according to claim 1,
wherein a bulk wave in a thickness slip mode in the piezoelectric layer is utilized.

11. A communication device comprising:
a filter including the elastic wave element according to claim 1;
an antenna connected to the filter; and
an integrated circuit element connected to the filter.
